(19) United States
(12) Patent Application Publication
(10) Pub. No.: US 2023/0215999 A1
(43) Pub. Date: Jul. 6, 2023

(54) LED DEVICE

(71) Applicant: FOSHAN NATIONSTAR OPTOELECTRONICS CO., LTD., Foshan (CN)

(72) Inventors: Libing PAN, Foshan (CN); Zhiguo XIE, Foshan (CN); Jiapeng ZHANG, Foshan (CN); Man ZHAO, Foshan (CN); Yinling ZHENG, Foshan (GD); Pingxia LIANG, Foshan (CN); Fuhai LI, Foshan (CN)

(73) Assignee: FOSHAN NATIONSTAR OPTOELECTRONICS CO., LTD., Foshan (CN)

(21) Appl. No.: 18/090,127

(22) Filed: Dec. 28, 2022

(30) Foreign Application Priority Data
Dec. 31, 2021 (CN) 202111680051.X
Dec. 31, 2021 (CN) 202123456443.6

(51) Int. Cl. H01L 33/60; H01L 33/62

(52) U.S. Cl. CPC H01L 33/60; H01L 33/62

(57) ABSTRACT

Provided is an LED device. The LED device includes a bracket and a chip. The bracket includes a lead frame and a molded structure connected to the lead frame. The molded structure includes a chip placement body and a reflective structure. The chip placement body defines an avoidance groove. The reflective structure is a cylindrical structure with an inner through hole. The inner through hole communicates with the avoidance groove. The cylindrical structure is disposed around the periphery of the chip placement body. A first end of the cylindrical structure is formed with an opening communicating with the inner through hole. A second end of the cylindrical structure is connected to the chip placement body in the entire circumferential direction. A circumferential sidewall of the inner through hole forms a reflective surface used for reflecting light.

### CROSS-REFERENCE TO RELATED APPLICATION

This application claims priority to Chinese Patent Applications No. 202111680051.X and 202123456443.6 both filed Dec. 31, 2021, the disclosure of each of which is incorporated herein by reference in its entirety.

### TECHNICAL FIELD

The present disclosure relates to the field of illumination technology and, in particular, to a light-emitting diode (LED) device.

### BACKGROUND

LEDs have advantages including a long service device, low power consumption, high response speed, environmental friendliness and the like. In addition to being widely used in traditional illumination fields, LEDs also have an increasingly wide application in emerging fields such as smart light poles, the illumination of plants, and visible light communication.

With the continuous expansion of the application of LED products, the market has increasingly high requirements for the luminescence efficiency and reliable performance of the LED products. However, an LED device in the related art fails to effectively reflect the light emitted from a chip of the LED device, thereby affecting the light emission rate of the LED device.

### SUMMARY

The present disclosure provides an LED device that has a relatively high light emission rate.

To achieve the preceding target, the present disclosure provides an LED device. The LED device includes a bracket and a chip. The bracket includes a lead frame and a molded structure connected to the lead frame. The molded structure includes a chip placement body and a reflective structure. The chip placement body defines an avoidance groove. The reflective structure is a cylindrical structure with an inner through hole. The inner through hole communicates with the avoidance groove. The cylindrical structure is disposed around the periphery of the chip placement body. A first end of the cylindrical structure is formed with an opening communicating with the inner through hole. A second end of the cylindrical structure is connected to the chip placement body in the entire circumferential direction. A circumferential sidewall of the inner through hole forms a reflective surface used for reflecting light. From the second end of the cylindrical structure to the first end of the cylindrical structure, the reflective surface includes a plurality of arc-shaped surfaces that are successively connected.

Further, the arc-shaped surfaces include a first arc-shaped surface and a second arc-shaped surface that are connected to each other. The first arc-shaped surface and the second arc-shaped surface are each inclined relative to the horizontal plane. The first arc-shaped surface and the second arc-shaped surface are each inclined in a direction gradually away from a center line of the cylindrical structure.

Further, a first included angle C1 is disposed between the first arc-shaped surface and the horizontal plane. The first included angle C1 satisfies that 25°≤C1≤50°. Alternatively and/or additionally, a second included angle D1 is disposed between the second arc-shaped surface and the horizontal plane. The second included angle D1 satisfies that 30°≤D1≤45°.

Further, the first arc-shaped surface protrudes toward the side where the center line is located. The first arc-shaped surface has a first radian α1, where 10°≤α1≤30°. Alternatively and/or additionally, the second arc-shaped surface protrudes in the direction away from the center line. The second arc-shaped surface has a second radian α2, where 40°≤α2≤80°.

Further, a first included angle C2 is disposed between the first arc-shaped surface and the horizontal plane. The first included angle C2 increases first and then decreases in the direction away from the center line. A second included angle D2 is disposed between the second arc-shaped surface and the horizontal plane. The second included angle D2 increases gradually in the direction away from the center line.

Further, the arc-shaped surfaces include a third arc-shaped surface connected to the second arc-shaped surface. The third arc-shaped surface is inclined relative to the horizontal plane and in the direction gradually away from the center line of the cylindrical structure.

Further, a third included angle is disposed between the third arc-shaped surface and the horizontal plane. The third included angle E1 satisfies that 30°≤E1≤40°. Alternatively and/or additionally, the third arc-shaped surface protrudes toward the side where the center line is located. The third arc-shaped surface has a third radian α3, where 40°≤α3≤80°.

Further, a first included angle C2 is disposed between the first arc-shaped surface and the horizontal plane. A second included angle D2 is disposed between the second arc-shaped surface and the horizontal plane. A third included angle E2 is disposed between the third arc-shaped surface and the horizontal plane. The first included angle C2 increases first and then decreases in the direction away from the center line. The second included angle D2 increases gradually in the direction away from the center line. The third included angle E2 decreases gradually in the direction away from the center line.

Further, the chip placement body 61 is a step structure used for mounting the chip.

Further, 0.7 W0≤W1≤0.9 W0, where W0 represents a width of the chip, and W1 represents a width of the avoidance groove. Alternatively, 0.15 H0≤H1≤0.35 H0, where H0 represents a height of the chip, and H1 represents a height of the step structure. Alternatively, 0.03 mm≤H1≤0.08 mm, where H1 represents a height of the step structure.

Further, the molded structure further includes a blocking member extending in the second direction and connected to the chip placement body. The blocking member is located on the side of the avoidance groove facing away from the inner through hole. A width of an end of the blocking member closer to the inner through hole is less than a width of an end of the blocking member farther from the inner through hole.

Further, the lead frame includes a first lead portion, a second lead portion, and a blocking structure. The first lead portion includes a first base. The second lead portion includes a second base spaced apart from the first base. A space between the first base and the second base forms a channel. The first lead portion and the second lead portion are insulated from each other. Part of the molded structure is filled in the channel. A side of at least one of the first base or the second base facing the channel is provided with the blocking structure. In the extension direction of the channel, the blocking structure is located between two opposite ends of the at least one of the first base or the second base and protrudes from the at least one of the first base or the second base. Part of the molded structure is located on a side of the lead frame. The blocking structure is exposed from the avoidance groove.

Further, the lead frame further includes a second recessed groove. The second recessed groove is disposed on the side of at least one of the first base or the second base facing away from the channel. The molded structure further includes a first protrusion connected to the reflective structure. The second recessed groove matches the first protrusion in shape and size.

Further, the projection of the reflective structure on a first plane and the projection of the chip placement body on the first plane completely cover the first protrusion to prevent the first protrusion from being exposed from the avoidance groove. Alternatively, the projection of the reflective structure on the first plane and the projection of the chip placement body on the first plane partially cover the first protrusion to enable part of the first protrusion to be exposed from the avoidance groove.

Further, a through hole is disposed on at least one of the first base or the second base. A second protrusion is disposed on a side of the molded structure. The second protrusion matches the through hole in shape and size.

Further, the LED device further includes at least one accommodation groove disposed on an inner wall surface of the cylindrical structure. The at least one accommodation groove is used for accommodating a Zener diode. Each of the at least one accommodation groove communicates with the inner through hole. Each of the at least one accommodation groove is spaced apart from the avoidance groove.

Further, an inclined surface is disposed on a sidewall of each of the at least one accommodation groove facing away from the chip placement body. From the second end of the cylindrical structure to the first end of the cylindrical structure, the inclined surface extends gradually away from a center line of the inner through hole.

Further, the inclined surface extends from the sidewall of the at least one accommodation groove to the first end of the cylindrical structure.

Further, the molded structure further includes a reflective member covering the at least one accommodation groove and used for reflecting light.

Further, the molded structure includes a plurality of accommodation grooves spaced apart in the circumferential direction of the avoidance groove.

### BRIEF DESCRIPTION OF DRAWINGS

To illustrate solutions in embodiments of the present disclosure more clearly, the accompanying drawings used in the description of the embodiments will be described below. Apparently, the accompanying drawings described below illustrate only part of the embodiments of the present disclosure, and those skilled in the art may obtain other accompanying drawings based on the accompanying drawings described below on the premise that no creative work is done.

FIG. 1 is a structure view of a bracket of an LED device according to embodiment one of the present disclosure.

FIG. 2 is a rear view of the bracket of FIG. 1.

FIG. 3 is a structure view of the LED device according to embodiment one of the present disclosure.

FIG. 4 is a right view of the bracket of FIG. 1.

FIG. 5 is a structure view of a lead frame of the bracket of FIG. 1.

FIG. 6 is a structure view of a bracket of an LED device according to embodiment two of the present disclosure.

FIG. 7 is a structure view of a bracket of an LED device according to embodiment three of the present disclosure.

FIG. 8 is a structure view of a bracket of an LED device according to embodiment four of the present disclosure.

FIG. 9 is a structure view of a bracket of an LED device according to embodiment five of the present disclosure.

FIG. 10 is a structure view of a bracket of an LED device according to embodiment six of the present disclosure.

FIG. 11 is a structure view of a bracket of an LED device according to embodiment seven of the present disclosure.

FIG. 12 is a structure view of a lead frame of a bracket of an LED device according to embodiment eight of the present disclosure.

FIG. 13 is a structure view of a bracket of an LED device according to embodiment nine of the present disclosure.

FIG. 14 is a structure view of a bracket of an LED device according to embodiment ten of the present disclosure.

FIG. 15 is a structure view of the LED device according to embodiment ten of the present disclosure.

FIG. 16 is an enlarged view of a dotted line area A in FIG. 3 according to embodiment one of the present disclosure.

### REFERENCE LIST

1 chip

10 lead frame

11 first base

12 channel

13 first recessed groove

14 indentation

15 second recessed groove

151 first groove segment

152 second groove segment

153 third groove segment

16 through hole

17 second base

20 first pin

30 second pin

40 molded structure

42 second arc-shaped structure

43 third arc-shaped structure

50 blocking structure

51 first arc-shaped structure

52 first protrusion portion

53 second protrusion portion

54 third protrusion portion

61 chip placement body

62 avoidance groove

64 first protrusion

65 blocking member

66 second protrusion

70 cylindrical structure

71 first arc-shaped surface

72 second arc-shaped surface

73 third arc-shaped surface

74 inner through hole

80 accommodation groove

81 inclined surface

### DETAILED DESCRIPTION

For a better understanding of the technical solutions by those skilled in the art, the solutions in embodiments of the present disclosure are described clearly and completely in conjunction with the drawings in embodiments of the present disclosure. Apparently, the embodiments described below are part, not all, of embodiments of the present disclosure. Based on the embodiments described herein, all other embodiments obtained by those skilled in the art on the premise that no creative work is done are within the scope of the present disclosure.

It is to be noted that the terms “first”, “second” and the like in the description, claims and drawings of the present disclosure are used to distinguish between similar objects and are not necessarily used to describe a particular order or sequence. It should be understood that the data used in this way is interchangeable where appropriate so that the embodiments of the present disclosure described herein may also be implemented in a sequence not illustrated or described herein. In addition, the terms “include”, “have” or any other variations thereof are intended to encompass a non-exclusive inclusion. For example, a process, method, system, product or equipment that includes a series of steps or units not only includes the expressly listed steps or units but may also include other steps or units that are not expressly listed or are inherent to such process, method, product or equipment.

It is to be noted that in embodiments of the present disclosure, an LED device includes a lead frame 10, a molded structure 40 located on a side of the lead frame 10, and a chip 1 located on a side of the molded structure 40 facing away from the lead frame 10. Moreover, part of the lead frame 10 is exposed to the molded structure 40 and is connected to the chip 1.

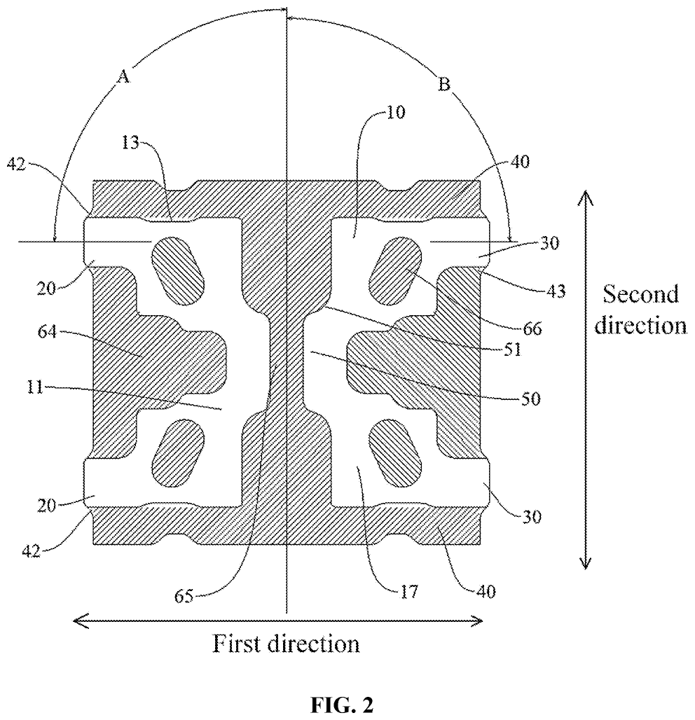

It is to be noted that in embodiments of the present disclosure, a first direction in FIG. 2 is perpendicular to an extension direction of a channel 12, and a second direction refers to a direction parallel to the extension direction of the channel 12.

It is to be noted that the lead frame 10 is made of a metal material in embodiments of the present disclosure.

It is to be noted that the molded structure 40 is made of a molding compound in embodiments of the present disclosure.

### Embodiment One

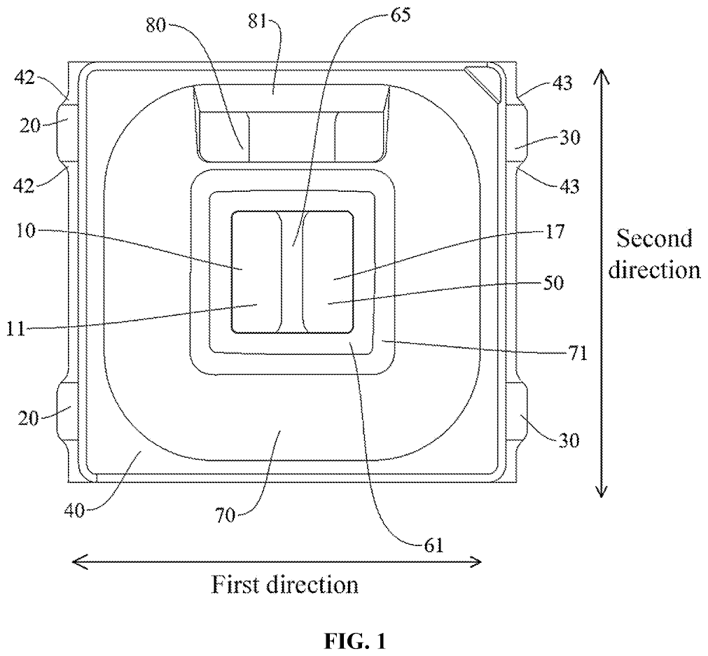

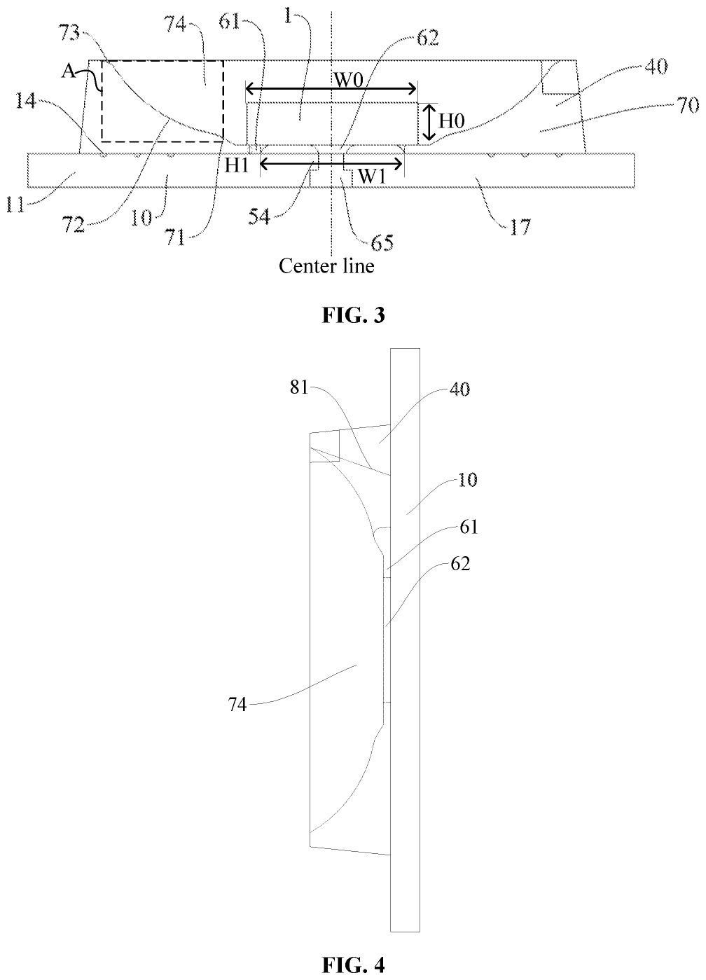

As shown in FIGS. 1 and 3, embodiment one of the present disclosure provides an LED device. The LED device includes a bracket and a chip 1. The bracket includes a lead frame 10 and a molded structure 40 connected to the lead frame 10. The molded structure 40 includes a chip placement body 61 and a reflective structure. The chip placement body 61 defines an avoidance groove 62. The reflective structure is a cylindrical structure 70 with an inner through hole 74. The inner through hole 74 communicates with the avoidance groove 62. The cylindrical structure 70 is disposed around the periphery of the chip placement body 61. A first end of the cylindrical structure 70 is formed with an opening communicating with the inner through hole 74. A second end of the cylindrical structure 70 is connected to the chip placement body 61 in the entire circumferential direction. A circumferential sidewall of the inner through hole 74 forms a reflective surface for reflecting light. From the second end of the cylindrical structure 70 to the first end of the cylindrical structure 70, the reflective surface includes a plurality of arc-shaped surfaces that are successively connected.

In the preceding technical solution, the reflective structure extends in the circumferential direction and is connected to the chip placement body 61 in the entire circumferential direction, so that the reflective structure has a relatively large reflective surface. That is, all the space of the molded structure 40 except for the chip placement body 61 is formed with the reflective structure. In this case, the reflective surface with a large area can reflect the light emitted from the chip located on the chip placement body 61, thereby effectively improving the light emission rate.

It is to be noted that in embodiment one of the present disclosure, the first end refers to an upper end of the reflective structure in FIG. 3. Since the reflective structure extends in the circumferential direction, the first end also extends in the circumferential direction. The second end refers to a lower end of the reflective structure in FIG. 3, i.e., an end of the reflective structure facing the chip placement body 61. Similarly, the second end extends in the circumferential direction.

Specifically, the reflective structure includes the arc-shaped surfaces that are successively connected. At the same height in FIG. 3, compared with a plane, the arc-shaped surfaces have a larger area, effectively increasing the area of the reflective surface, thereby enabling the reflective surface to better reflect the light emitted from the chip 1, and thus effectively improving the light emission rate.

As shown in FIG. 3 and FIG. 16, in embodiment one of the present disclosure, the arc-shaped surfaces include a first arc-shaped surface 71 and a second arc-shaped surface 72 that are connected to each other. The first arc-shaped surface 71 and the second arc-shaped surface 72 are each inclined relative to the horizontal plane. The first arc-shaped surface 71 and the second arc-shaped surface 72 are each inclined in a direction gradually away from a center line of the cylindrical structure 70.

The preceding arrangement enables the reflective structure to be formed with the cylindrical structure 70 with an upward opening, i.e., a bowl-shaped structure. In this case, the reflective structure may face the chip 1 so that the light emitted from the chip 1 is emitted to the reflective surface. Moreover, the reflective structure may also face above the chip 1 so that the reflective surface reflects, in a direction away from the chip 1, the light emitted from the chip 1, thereby effectively improving the reflective effect of the reflective structure.

As shown in FIG. 3 and FIG. 16, in embodiment one of the present disclosure, a first included angle C1 is disposed between the first arc-shaped surface 71 and the horizontal plane. The first included angle C1 satisfies that 25°≤C1≤50°.

The preceding arrangement enables the first arc-shaped surface 71 to extend in the direction away from the chip placement body 61 first, reducing the entire inclination of the reflective surface, increasing the area of the reflective surface in the horizontal direction in FIG. 3, and reducing the height of the reflective surface in the vertical direction in FIG. 3. In this case, the reflective surface is able to reflect, in the direction away from the chip 1, the light emitted from the chip 1.

As shown in FIG. 3 and FIG. 16, in embodiment one of the present disclosure, a second included angle D1 is disposed between the second arc-shaped surface 72 and the horizontal plane. The second included angle D1 satisfies that 30°≤D1≤45°.

The preceding arrangement enables the second arc-shaped surface 72 to extend upwardly in the vertical direction in FIG. 3, which prevents the reflected light from be scattered around and thereby improves the light emission rate of the LED device.

As shown in FIG. 3 and FIG. 16, in embodiment one of the present disclosure, the first arc-shaped surface 71 protrudes toward the side where the center line is located. The first arc-shaped surface 71 has a first radian α1, where 10°≤α1≤30°.

The preceding arrangement increases the area of the first arc-shaped surface 71 in the case of reducing the entire inclination of the reflective surface and making the first arc-shaped surface 71 extend in the direction away from the chip placement body 61, thereby increasing the area of the reflective surface and thus effectively improving the reflective effect of the reflective structure.

As shown in FIG. 3 and FIG. 16, in embodiment one of the present disclosure, the second arc-shaped surface 72 protrudes in the direction away from the center line. The second arc-shaped surface 72 has a second radian α2, where 40°≤α2≤80°. Similarly, the preceding second arc-shaped surface 72 can have the same effect as the preceding first arc-shaped surface 71, which is not repeated here.

As shown in FIG. 3 and FIG. 16, in embodiment one of the present disclosure, a first included angle C2 is disposed between the first arc-shaped surface 71 and the horizontal plane. The first included angle C2 increases first and then decreases in the direction away from the center line. A second included angle D2 is disposed between the second arc-shaped surface 72 and the horizontal plane. The second included angle D2 increases gradually in the direction away from the center line.

The preceding arrangement enables the first arc-shaped surface 71 to protrude toward the side where the center line is located and enables the second arc-shaped surface 72 to protrude in the direction away from the center line, thereby increasing the area of the first arc-shaped surface 71 and the area of the second arc-shaped surface 72, thus increasing the area of the reflective surface, and achieving the object of improving the reflective effect of the reflective structure.

As shown in FIG. 3 and FIG. 16, in embodiment one of the present disclosure, the arc-shaped surfaces further include a third arc-shaped surface 73 connected to the second arc-shaped surface 72. The third arc-shaped surface 73 is inclined relative to the horizontal plane. The third arc-shaped surface 73 may be inclined in the direction gradually away from the center line of the cylindrical structure 70.

In the preceding technical solution, the third arc-shaped surface 73 is added in addition to two arc-shaped surfaces, further increasing the reflective area of the reflective structure and thereby better improving the light emission rate of the LED device.

As shown in FIG. 3 and FIG. 16, in embodiment one of the present disclosure, a third included angle E1 is disposed between the third arc-shaped surface 73 and the horizontal plane. The third included angle E1 satisfies that 30°≤E1≤40°.

The preceding arrangement increases both the area of the reflective surface in the vertical direction and the area of the reflective surface in the horizontal direction, thereby enabling the bowl-shaped structure shown in FIG. 3 to be formed. In this case, the light emitted from the chip 1 is better reflected to improve the light emission rate.

It is to be noted that in embodiment one of the present disclosure, the first included C1 refers to an included angle between the horizontal plane and a connection line of two ends of an arc projected by the first arc-shaped surface 71 on the paper surface in FIG. 3 and FIG. 16. The second included angle D1 and the third included angle E1 are obtained in the same manner, which is not repeated here.

As shown in FIG. 3 and FIG. 16, in embodiment one of the present disclosure, the third arc-shaped surface 73 protrudes toward the side where the center line is located. The third arc-shaped surface 73 has a third radian α3, where 40°≤α3≤80°. Similarly, the preceding third arc-shaped surface 73 can have the same effect as the preceding first arc-shaped surface 71 and the preceding second arc-shaped surface 72, which is not repeated here.

It is to be noted that in embodiments of the present disclosure, the first radian, the second radian and the third radian refer to a value of a central angle corresponding to the first arc-shaped surface 71, a value of a central angle corresponding to the second arc-shaped surface 72, and a value of a central angle corresponding to the third arc-shaped surface 73 respectively. For example, the first radian refers to the value of the central angle corresponding to the arc of the first arc-shaped surface 71 on the section shown in FIG. 3. Similarly, the calculation method of the second radian and the calculation method of the third radian are the same as the calculation method of the first radian.

Preferably, as shown in FIG. 3 and FIG. 16, in embodiment one of the present disclosure, the reflective surface includes the first arc-shaped surface 71, the second arc-shaped surface 72, and the third arc-shaped surface 73 that are successively connected. A first included angle C2 is disposed between the first arc-shaped surface 71 and the horizontal plane. A second included angle D2 is disposed between the second arc-shaped surface 72 and the horizontal plane. A third included angle E2 is disposed between the third arc-shaped surface 73 and the horizontal plane. In the direction away from the center line, the first included angle C2 increases first and then decreases, the second included angle D2 increases gradually, and the third included angle E2 decreases gradually.

The preceding arrangement enables the first arc-shaped surface 71 to protrude toward the side where the center line is located, enables the second arc-shaped surface 72 to protrude in the direction away from the center line, and enables the third arc-shaped surface 73 to protrude toward the side where the center line is located. In this case, the area of the first arc-shaped surface 71, the area of the second arc-shaped surface 72, and the area of the third arc-shaped surface 73 are increased, thus increasing the area of the reflective surface and effectively improving the reflective effect of the reflective structure.

It is to be noted that in embodiment one of the present disclosure, the first included angle C2 refers to an included angle between a tangent plane of the first arc-shaped surface 71 and the horizontal plane. For example, the first included angle C2 is an included angle between the horizontal plane and a tangent line at any point of the arc of the first arc-shaped surface 71 on the section shown in FIG. 3. The second included angle D2 and the third included angle E2 are obtained in the same manner, which is not repeated here.

As shown in FIGS. 3 and 4, in embodiment one of the present disclosure, the chip placement body 61 is a step structure used for mounting the chip.

In the preceding technical solution, the chip placement body 61 is provided to be a step structure so that the soldering height of the chip 1 is increased and the area of a metal layer (the upper surface of the lead frame 10) at the bottom of the chip 1 is reduced. The bottom of the chip 1 can be close to the molded structure 40, thereby avoiding the problem that brightness reduction is caused by the light emitted from the four sides of the chip 1 and reflected to the bottom of the chip 1 through the metal layer (the upper surface of the lead frame 10). Thus, the light emission of the product is improved.

Further, the step structure may position the chip 1 so that the chip 1 is mounted in the center line of the reflective structure. Accordingly, the reflective surface has the same distance from the chip 1 in the circumferential direction, improving the uniformity of the light reflection of the reflective structure and thereby improving the uniformity of the light emission of the LED device.

Further, the arrangement of the step structure can raise the chip 1 and prevent the uneven solder paste between the chip 1 and the lead frame 10 from supporting the chip 1, thereby avoiding the problem of mounting the chip 1 unevenly and thus avoiding the problem that brightness reduction is caused by the light emitted from the four sides of the chip 1 and reflected to the bottom of the chip 1 through the metal layer (the upper surface of the lead frame 10).

As shown in FIGS. 3 and 4, in embodiment one of the present disclosure, 0.7 W0≤W1≤0.9 W0, where W0 represents a width of the chip, and W1 represents a width of the avoidance groove. In this case, the step structure can support the chip 1, and the avoidance groove 62 can avoid the solder paste.

As shown in FIGS. 3 and 4, in embodiment one of the present disclosure, 0.15 H0≤H1≤0.35 H0, where H0 represents a height of the chip, and H1 represents a height of the step structure. With this arrangement, it can be avoided that due to a too low height of the step structure, the solder paste protrudes from the step structure to cause uneven mounting of the chip 1, and it can also be avoided that due to a too high height of the step structure, the mounting height of the chip 1 is too high, and thus the reflective surface of the reflective structure cannot be fully used for light emission.

Preferably, in embodiment one of the present disclosure, 0.03 mm≤H1≤0.08 mm, where H1 represents a height of the step structure.

Preferably, in embodiment one of the present disclosure, a distance of the chip 1 protruding from the step structure is 100 μm to 250 μm.

With continued reference to FIG. 1, the LED device further includes at least one accommodation groove 80 disposed on an inner wall surface of the cylindrical structure 70. The at least one accommodation groove 80 is used for accommodating a Zener diode. The at least one accommodation groove 80 communicates with the inner through hole 74.

With the preceding arrangement, the at least one accommodation groove 80 can accommodate a Zener diode, providing convenience for the processing personnel to mount the Zener diode on the molded structure and connect the Zener diode to the lead frame 10, thereby improving the production efficiency of an encapsulation structure.

Specifically, in this embodiment, the accommodation groove 80 is a through groove, thereby enabling the Zener diode to be connected to the lead frame 10.

Preferably, in this embodiment, one accommodation groove 80 is provided. One end of the accommodation groove 80 is used for accommodating the Zener diode, and the other end of the accommodation groove 80 is used for wiring.

Preferably, in this embodiment, the accommodation groove 80 is rectangular. Of course, in an alternative embodiment not shown in the drawings, the accommodation groove 80 may also be square or in another shape capable of accommodating the Zener diode.

As shown in FIGS. 1 and 4, in this embodiment, an inclined surface 81 is disposed on a sidewall of the accommodation groove 80 farther away from the chip placement body 61. From the second end of the cylindrical structure 70 to the first end of the cylindrical structure 70, the inclined surface 81 extends gradually away from a center line of the inner through hole 74.

Specifically, an included angle between the inclined surface 81 and the horizontal plane is greater than or equal to 70° and less than or equal to 80°.

The preceding arrangement enables the inclined surface 81 to face above the chip so that the inclined surface 81 reflects, in the direction away from the chip, the light emitted from the chip, thereby effectively improving the reflective effect of the reflective structure. Of course, in an alternative embodiment, the inclined surface 81 may face the chip so that the light emitted from the chip is irradiated onto the inclined surface 81.

As shown in FIGS. 1 and 4, in this embodiment, the inclined surface 81 extends from the sidewall of the accommodation groove 80 to the first end of the cylindrical structure.

The preceding arrangement increases the area of the inclined surface 81, thereby increasing the reflective area of the reflected light and thus improving the reflective effect of the inclined surface 81. Further, the preceding arrangement facilitates the die bonding and subsequent wiring operation of the Zener diode.

Of course, in an alternative embodiment, the molded structure may include a plurality of accommodation grooves 80 spaced apart in the circumferential direction of the avoidance groove 62. In this case, a plurality of Zener diodes may be disposed in the plurality accommodation grooves 80, thereby improving the voltage regulation capability and antistatic capability of the encapsulation structure.

Of course, in an alternative embodiment, the molded structure may include two accommodation grooves 82. The two accommodation grooves 82 are symmetrical about the avoidance groove 62 or are spaced apart in the circumferential direction of the avoidance groove 62.

As shown in FIG. 1, in this embodiment, the accommodation groove 80 is spaced apart from the avoidance groove 62.

With the preceding arrangement, a space between an accommodation groove 80 and the avoidance groove 62 is filled by the reflective structure having the function of reflection, thereby ensuring the reflective area of the reflective structure as much as possible in the case where the accommodation groove 80 is provided. Thus, the reflective effect of the reflective structure is ensured.

It is to be noted that in this embodiment, the arrangement of the preceding space indicates that the accommodation groove 80 does not communicate with the avoidance groove 62.

In this embodiment, the encapsulation structure further includes a reflective member covering the accommodation groove 80 to reflect light.

In the preceding technical solution, the arrangement of the reflective member increases the reflective area of the reflected light, thereby avoiding the problem that the lead frame 10 exposed from the Zener diode and the at least one accommodation groove 80 absorbs light and causes the reduction of luminescence efficiency. Thus the light emission rate of the encapsulation structure is improved

Specifically, in this embodiment, after the Zener diode is mounted in the accommodation groove 80, the reflective member covers the accommodation groove 80 and the Zener diode. With this arrangement, in the case where the Zener diode is provided, the reflective area of the molded structure 40 is still ensured.

Specifically, in this embodiment, the reflective member covers the entire accommodation groove 80. Moreover, after the reflective member is filled, the upper surface of the reflective member almost coincides with the original reflective surface in radian to form a continuously smooth surface.

Preferably, in this embodiment, the reflective member is made of highly reflective powder and a colloidal material. That is, the accommodation groove 80 is filled by the highly reflective powder and the colloidal material and the Zener diode is covered by the highly reflective powder and the colloidal material.

Specifically, the colloidal material may be formed by epoxy resin, silicone resin, or silica gel. The highly reflective powder may include ceramic powder with a high reflectance, such as TiO₂, Al₂O₃, Nb₂O₅, or ZnO. Alternatively, the highly reflective powder may include metal powder with a high reflectance (such as Al or Ag).

As shown in FIGS. 1, 2, 3, and 5, in embodiment one of the present application, the lead frame 10 includes a first lead portion, a second lead portion, and a blocking structure 50. The first lead portion includes a first base 11. The second lead portion includes a second base 17 spaced apart from the first base 11. A space between the first base 11 and the second base 17 forms a channel 12. The first lead portion and the second lead portion are insulated from each other. Part of the molded structure 40 is filled in the channel 12. A side of at least one of the first base 11 or the second base 17 facing the channel 12 is provided with the blocking structure 50. In the extension direction of the channel 12, the blocking structure 50 is located between two opposite ends of the least one of the first base 11 or the second base 17 and protrudes from the least one of the first base 11 or the second base 17. Part of the molded structure 40 is located on a side of the lead frame 10. The blocking structure 50 is exposed from the avoidance groove 62.

In the preceding technical solution, the blocking structure 50 is provided to allow the channel 12 to form a “wide-narrow-wide” pattern, providing an enough soldering area for the soldering between the lead frame 10 and the chip 1, reducing the possibility of flux intruding into the chip placement region, thereby avoiding the problem of reduced air tightness due to the thermal deformation of the lead frame 10 during soldering, and thus improving the reliability of the LED device.

As shown in FIGS. 1, 2, 3, and 5, in embodiment one of the present application, part of the molded structure 40 is located on the side of the lead frame 10, and the avoidance groove 62 corresponding to the blocking structure 50 is disposed on the molded structure 40 so that the blocking structure 50 is exposed from the avoidance groove 62.

With the preceding arrangement, the avoidance groove 62 enables the blocking structure 50 to be exposed, thereby facilitating the soldering between the chip 1 and the blocking structure 50 and thus improving the connection stability between the chip 1 and the lead frame 10.

It is to be noted that in embodiment one of the present disclosure, the channel 12 includes only three groove segments successively connected in the second direction. Lengths of two opposite ends of the channel 12 refer to the maximum lengths of groove segments on two ends of the three groove segments in the first direction. A length of the middle part of the channel 12 refers to a length of a groove segment in the middle of the three groove segments in the first direction. In this case, the length in the middle of the channel 12 is relatively small, and the length of each end of the channel 12 is relatively great. That is, the “wide-narrow-wide” pattern in FIG. 2 is formed.

Preferably, in embodiment one of the present disclosure, a side of each of the first lead portion and the second lead portion facing the channel 12 is provided with a blocking structure 50 so that the “I-shaped” channel 12 is formed.

Preferably, in embodiment one of the present disclosure, the blocking structure 50 may be a rib protruding from a lead portion.

It is to be noted that in embodiment one of the present disclosure, the side of at least one of the first base 11 or the second base 17 facing the channel 12 is provided with the blocking structure 50. This arrangement refers to that the blocking structure 50 is disposed on the first base 11, the blocking structure 50 is disposed on the second base 17, or each of the first base 11 and the second base 17 is provided with a blocking structure 50.

As shown in FIGS. 1, 2, and 5, in embodiment one of the present disclosure, the lead frame 10 includes two blocking structures 50. Each of the first base 11 and the second base 17 is provided with one blocking structure 50. The two blocking structures 50 are staggered in the extension direction of the channel 12 and have the same length in the first direction perpendicular to the extension direction of the channel 12.

In the preceding technical solution, each of the first base 11 and the second base 17 is provided with one blocking structure 50. Compared with the arrangement of only one blocking structure 50, this arrangement increases the connection area between the lead frame 10 and the molded structure 40 as much as possible, thereby enabling the lead frame 10 to be stably combined with the molded structure 40 and thus improving the reliability of the LED device.

It is to be noted that the two blocking structures 50 are staggered in embodiment one of the present disclosure. This arrangement refers to that in the extension direction of the channel, at least one end of a blocking structure 50 on the first base 11 protrudes from a blocking structure 50 on the second base 17. That is, in the extension direction of the channel, one end of the blocking structure 50 on the first base 11 may protrude from one end of the blocking structure 50 on the second base 17, and the other end of the blocking structure 50 on the second base 17 may protrude from the other end of the blocking structure 50 on the first base 11. Alternatively, in the extension direction of the channel, each end of the blocking structure 50 on the first base 11 protrudes from a respective end of the blocking structure 50 on the second base 17.

As shown in FIGS. 1, 2, and 5, in embodiment one of the present disclosure, the lead frame 10 includes two blocking structures 50. Each of the first base 11 and the second base 17 is provided one blocking structure 50. The two blocking structures 50 are symmetrical about the channel 12.

Two electrodes of the chip 1 are symmetrical. Accordingly, the preceding arrangement enables the two blocking structures 50 to be better soldered with the two electrodes of the chip 1. Moreover, with the preceding arrangement, the structure is simple and easy to process.

As shown in FIGS. 1, 2, and 5, in embodiment one of the present disclosure, the width of the blocking structure 50≥0.25 times the width of the first base 11 or the second base 17, and the width of the blocking structure 50≤0.5 times the width of the first base 11 or the second base 17.

In the preceding technical solution, the width of the blocking structure 50 is greater than or equal to 0.25 times the width of the first base 11 or the second base 17 so as to ensure an enough soldering area between the chip 1 and the lead frame 10. The width of the blocking structure 50 is less than or equal to 0.5 times the width of the first base 11 or the second base 17 so as to avoid a reduction in the width of the channel 12 (that is, the length of the channel 12 in the extension direction of the channel 12), thereby avoiding a short circuit between the first lead portion and the second lead portion during soldering.

Preferably, in embodiment one of the present disclosure, the width of the blocking structure 50 is equal to 0.3 times the width of the first base 11 or the second base 17.

It is to be noted that in embodiment one of the present disclosure, the width of the blocking structure 50 refers to the length of the blocking structure 50 in the extension direction of the channel 12.

As shown in FIGS. 1, 2, and 5, in embodiment one of the present disclosure, the length of two opposite ends of the channel 12≥0.1 times the sum of the maximum lengths of the first base 11, the channel 12 and the second base 17, and the length of the two opposite ends of the channel 12≤0.3 times the sum of the maximum lengths of the first base 11, the channel 12 and the second base 17.

In the preceding technical solution, the length of the two opposite ends of the channel 12 is greater than or equal to 0.1 times the sum of the maximum lengths of the first base 11, the channel 12 and the second base 17 so as to avoid a short circuit between the first lead portion and the second lead portion during soldering. The length of the two opposite ends of the channel 12 is less than or equal to 0.3 times the sum of the maximum lengths of the first base 11, the channel 12 and the second base 17 so as to ensure an enough contact area between the lead frame 10 and the molded structure 40, thereby ensuring an enough binding force between the lead frame 10 and the molded structure 40, improving the air tightness of the LED device, avoiding the deformation of the blocking structure 50, and improving the effect of heat dissipation.

Preferably, in embodiment one of the present disclosure, the length of the two opposite ends of the channel 12 is equal to 0.15 times the sum of the maximum lengths of the first base 11, the channel 12 and the second base 17.

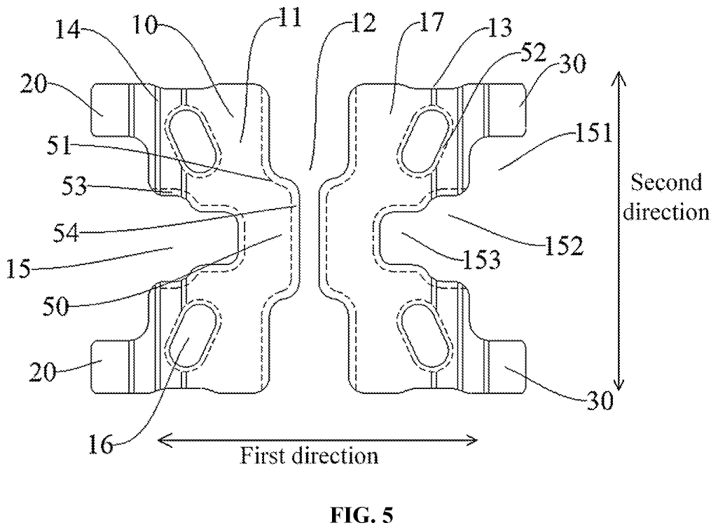

As shown in FIGS. 2 and 5, in embodiment one of the present disclosure, the lead frame 10 further includes a first arc-shaped structure 51 located on the side of the first base 11 facing the channel 12. In the extension direction of the channel 12, at least one side of the blocking structure 50 on the first base 11 is provided with a first arc-shaped structure 51, through which the blocking structure 50 is smoothly connected to the first lead portion. The lead frame 10 further includes a first arc-shaped structure 51 located on the side of the second base 17 facing the channel 12. In the extension direction of the channel 12, at least one side of the blocking structure 50 on the second base 17 is provided with a first arc-shaped structure 51, through which the blocking structure 50 is smoothly connected to the second lead portion.

The preceding arrangement reduces the concentrated stress at the connection between a blocking structure 50 and a lead portion, thereby improving the strength of the lead frame 10. Further, the preceding structure is simple and easy to process.

Further, the arrangement of a first arc-shaped structure 51 increases the binding force between the lead frame 10 and the molded structure 40 so that the lead frame 10 can be more stably connected to the molded structure 40.

Preferably, in embodiment one of the present disclosure, the arrangement of a first arc-shaped structure 51 implements a smooth connection between the first arc-shaped structure 51 and a lead portion. Preferably, the first arc-shaped structure 51 is an arc-shaped chamfer that is easy to process.

Preferably, in embodiment one of the present disclosure, two opposite sides of a blocking structure 50 are each provided with a first arc-shaped structure 51 so that the two opposite sides of the blocking structure 50 can be smoothly connected to a lead portion.

Of course, in an alternative embodiment not shown in the drawings, only one side of a blocking structure 50 may be provided with a first arc-shaped structure 51.

As shown in FIGS. 2 and 5, in embodiment one of the present disclosure, the lead frame 10 further includes a first recessed groove 13. In the extension direction of the channel 12 (that is, the second direction), at least one side of at least one of the first base 11 or the second base 17 is each provided with a first recessed groove 13.

In the preceding technical solution, the at least one side of the at least one of the first base 11 or the second base 17 is each provided with the first recessed groove 13 so that the edge length of the lead frame 10 is increased, thereby effectively increasing the connection area between the lead frame 10 and the molded structure 40, making the connection between the lead frame 10 and the molded structure 40 more stable, and thus improving the stability of the LED device.

Further, the arrangement of the first recessed groove 13 reduces the thermal deformation of a bulk copper layer during soldering, that is, reducing the thermal deformation of at least one of the first base or the second base.

Preferably, in embodiment one of the present disclosure, in the extension direction of the channel 12 (that is, the second direction), two opposite sides of the first base 11 are each provided with a first recessed groove 13, and two opposite sides of the second base 17 are each provided with a first recessed groove 13. Compared with the arrangement of only one first recessed groove 13, the preceding arrangement enables a larger connection area between the lead frame 10 and the molded structure 40 to make the LED device more stable.

It is to be noted that in embodiment one of the present disclosure, the at least one side of at least one of the first base 11 or the second base 17 is each provided with the first recessed groove 13 in the extension direction of the channel 12. This arrangement refers to that at least one of an upper side or a lower side of at least one of the first base 11 or the second base 17 is each provided with a first recessed groove 13 in the extension direction of the channel 12 in FIG. 2. That is, at least one side of only one of the first base 11 and the second base 17 may be provided with a first recessed groove 13. Alternatively, at least one side of each of the first base 11 and the second base 17 may be provided with a first recessed groove 13.

Of course, in an alternative embodiment not shown in the drawings, the upper and lower sides of only the first base 11 or second base 17 may be each provided with a first recessed groove 13.

As shown in FIGS. 1, 2, and 5, in embodiment one of the present disclosure, the lead frame 10 further includes a second recessed groove 15. The second recessed groove 15 is disposed on the side of at least one of the first base 11 or the second base 17 facing away from the channel 12. The molded structure 40 further includes a first protrusion 64 connected to the reflective structure. The second recessed groove 15 matches the first protrusion 64 in shape and size.

The preceding arrangement enables the inner wall of the second recessed groove 15 to better mate with the outer wall of the first protrusion 64, thereby increasing the binding force between the molded structure 40 and the lead frame 10, thus improving the connection stability between a pin and the molded structure, and improving the air tightness between the lead frame 10 and the molded structure 40.

Preferably, in embodiment one of the present disclosure, each of the first base 11 and the second base 17 is provided with a second recessed groove 15. Each second recessed groove 15 is provided with a first protrusion 64.

As shown in FIGS. 2 and 5, in embodiment one of the present disclosure, each second recessed groove 15 includes at least two groove segments communicating with each other. Moreover, in the first direction toward the channel 12, widths of the at least two groove segments decrease successively.

The preceding arrangement effectively improves the connection stability between the lead frame 10 and the molded structure 40 and reduces the thermal deformation of the bulk copper layer during soldering, that is, reducing the thermal deformation of at least one of the first base or the second base. Thus, the air tightness between the lead frame 10 and the molded structure 40 is improved.

Specifically, in embodiment one of the present disclosure, a ratio in width of two adjacent groove segments is 1 to 2.

As shown in FIGS. 2 and 5, in embodiment one of the present disclosure, the at least two groove segments include a first groove segment 151, a second groove segment 152, and a third groove segment 153 that are communicated successively. Moreover, in the direction toward the channel 12, a width of the first groove segment 151, a width of the second groove segment 152, and a width of the third groove segment 153 decrease successively.

The preceding arrangement effectively improves the connection stability between the lead frame 10 and the molded structure 40, improves the connection strength between the pin and the base, and thereby avoids the deformation of the pin.

In the preceding technical solution, the width of the first groove segment 151, the width of the second groove segment 152, and the width of the third groove segment 153 decrease successively, which facilitates the processing of the lead frame 10.

It is to be noted that in embodiment one of the present disclosure, the width of the first groove segment 151, the width of the second groove segment 152, and the width of the third groove segment 153 refer to a length of the first groove segment 151 in the second direction, a length of the second groove segment 152 in the second direction, and a length of the third groove segment 153 in the second direction respectively.

Of course, in an alternative embodiment not shown in the drawings, the width of the first groove segment 151 is greater than the width of the second groove segment 152, and the width of the second groove segment 152 is less than the width of the third groove segment 153.

Preferably, as shown in FIG. 1, in embodiment one of the present disclosure, projections of the reflective structure and the chip placement body 61 on a first plane completely cover the first protrusion 64 to prevent the first protrusion 64 from being exposed from the avoidance groove 62.

It is to be noted that in embodiment one of the present disclosure, the first plane refers to a plane shown in FIG. 1, i.e., the paper surface in FIG. 1.

As shown in FIGS. 1 and 3, in embodiment one of the present disclosure, the molded structure 40 further includes a blocking member 65 which extends in the second direction and is connected to the chip placement body 61. The blocking member 65 is located on the side of the avoidance groove 62 facing away from the inner through hole 74 and mates with the channel 12. In the vertical direction in FIG. 3, a width of an end of the blocking member 65 closer to the inner through hole 74 is less than a width of an end of the blocking member 65 farther from the inner through hole 74.

It is to be noted that in embodiment one of the present disclosure, the blocking member 65 includes three blocking segments that are successively connected in the extension direction of the channel 12. In the extension direction of the channel 12, a width of a blocking segment at each of two ends of the three blocking segments of the preceding blocking member 65 is greater than a width of a blocking segment in the middle of the three blocking segments of the blocking member 65. In this case, the blocking member 65 has a larger width in the middle and a smaller width at the two ends. That is, a “wide-narrow-wide” pattern matching the channel 12 in FIG. 1 can be formed.

Preferably, in embodiment one of the present disclosure, the blocking member 65 is “I-shaped” to better mate with the channel 12.

In the preceding technical solution, through the arrangement of the blocking member 65, the blocking member 65 mates with the channel 12 to enable a larger connection area between the molded structure 40 and the lead frame 10, thereby increasing the binding force between the molded structure 40 and the lead frame 10. Further, an electroplating region between the chip 1 and the lead frame 10 is also reduced, improving the reliability of high-temperature aging and effectively improving the light emission rate of the LED device.

As shown in FIGS. 2 and 5, in embodiment one of the present disclosure, a through hole 16 is disposed on at least one of the first base 11 or the second base 17. A second protrusion 66 is disposed on a side of the molded structure 40. The second protrusion 66 matches the through hole 16 in size and shape.

The preceding arrangement enables an inner wall of the through hole 16 to mate with an outer wall of the second protrusion 66, thereby increasing the binding force between the lead frame 10 and the molded structure 40.

Preferably, in embodiment one of the present disclosure, each of the first base 11 and the second base 17 is provided with a through hole 16 corresponding to a second protrusion 66, which enables a larger binding force between the lead frame 10 and the molded structure 40.

Of course, in an alternative embodiment not shown in the drawings, only one of the first base 11 and the second base 17 may be provided with a through hole 16.

As shown in FIGS. 2 and 5, in embodiment one of the present disclosure, the through hole 16 is an elongated hole. An included angle is disposed between a length direction of the through hole 16 and the extension direction of the channel 12.

In the preceding technical solution, the through hole 16 is provided to be the elongated hole so that the area of a copper layer of the lead frame 10 is reduced, thereby reducing the expansion of the lead frame 10 heated during soldering and thereby increasing the air tightness of the bracket.

Further, the arrangement of the included angle between the length direction of the through hole 16 and the extension direction of the channel 12 can not only increase the binding force of the through hole 16 and the molded structure 40 in both the first and second direction and increases the binding force of the through hole 16, but also increase the molded structure 40 in the second direction.

Preferably, as shown in FIG. 2, in embodiment one of the present disclosure, an included angle is disposed between the length direction of the elongated hole and the extension direction of the channel 12, and a distance between an upper end of the elongated hole and a median line of the channel 12 is greater than a distance between a lower end of the elongated hole and the median line of the channel 12.

Of course, in an alternative embodiment not shown in the drawings, the through hole 16 may also be an oval through hole.

As shown in FIGS. 2 and 5, in embodiment one of the present disclosure, a plurality of through holes 16 are provided. The plurality of through holes 16 are spaced apart in the extension direction of the channel 12.

In the preceding technical solution, the increased number of through holes 16 can increase the connection area between the lead frame 10 and the molded structure 40, thereby increasing the binding force between the lead frame 10 and the molded structure 40.

Preferably, as shown in FIGS. 2 and 5, in embodiment one of the present disclosure, two through holes 16 are provided in the extension direction of the channel 12. Of course, in an alternative embodiment not shown in the drawings, the number of through holes 16 may be, for example, three or four.

As shown in FIGS. 1 and 5, in embodiment one of the present disclosure, the lead frame 10 further includes a first protrusion portion 52 connected to an inner wall surface of a through hole 16. The first protrusion portion 52 extends toward the inner side of the through hole 16 to increase the connection area between the lead frame 10 and the molded structure 40.

In the preceding technical solution, the first protrusion portion 52 is disposed on the inner wall surface of the through hole 16 so that a step surface is formed between the inner wall surface of the through hole 16 and the first protrusion portion 52, thereby increasing the contact area between the through hole 16 and the molded structure 40, thus increasing the connection area between the lead frame 10 and the molded structure 40, and effectively improving the connection stability between the lead frame 10 and the molded structure 40.

Preferably, in embodiment one of the present disclosure, the first protrusion portion 52 includes an annular rib. In this case, the first protrusion portion is relatively simple in structure and is easy to process.

Of course, in an alternative embodiment, a first protrusion portion 52 may also include a plurality of raised rib segments spaced apart in the circumferential direction of a through hole.

As shown in FIG. 5, in embodiment one of the present disclosure, the bracket further includes a second protrusion portion 53. A peripheral edge of at least one of the first base 11 or the second base 17 is provided with the second protrusion portion 53.

In the preceding technical solution, the peripheral edge of at least one of the first base 11 or the second base 17 is provided with the second protrusion portion 53 so that the contact area between the lead frame 10 and the molded structure 40 is increased. Similarly, the preceding second protrusion portion 53 can have the same effect as the preceding first protrusion portion 52, which is not repeated here.

Preferably, in embodiment one of the present disclosure, the second protrusion portion 53 includes an elongated raised rib, which is easy to process.

Of course, in an alternative embodiment, the second protrusion portion 53 may include a plurality of raised rib segments spaced apart along the peripheral edge of the first base 11 and the peripheral edge of the second base 17.

As shown in FIGS. 1, 3, and 5, the bracket further includes a third protrusion 54. The third protrusion portion 54 is disposed on a side of the lead frame 10 facing the channel 12.

In the preceding technical solution, the third protrusion portion 54 is disposed on the side of the lead frame 10 facing the channel 12 so that a step surface is formed between the side of the lead frame 10 facing the channel 12 and the third protrusion portion 54, thereby increasing the contact area between the lead frame 10 and the molded structure 40 and effectively improving the connection stability between the lead frame 10 and the molded structure 40. Further, the arrangement of the third protrusion portion 54 increases the air tightness between the lead frame 10 and the molded structure 40.

Preferably, as shown in FIG. 1, in embodiment one of the present disclosure, the third protrusion portion 54 includes an elongated raised rib, which is easy to process.

Of course, in an alternative embodiment in the drawings, the third protrusion portion 54 may include a plurality of raised rib segments spaced apart along an edge of the lead frame 10.

As shown in FIGS. 1, 2, and 5, in embodiment one of the present disclosure, the first lead portion further includes a plurality of first pins 20 protruding from the first base 11, and the second lead portion further includes a plurality of second pins 30 protruding from the second base 17. An included angle is disposed between an extension direction of each first pin 20 and the extension direction of the channel 12. An included angle is disposed between an extension direction of each second pin 30 and the extension direction of the channel 12. The first pins 20 are located on the side of the first base 11 facing away from the channel 12. The second pins 30 are located on the side of the second base 17 facing away from the channel 12.

In the preceding technical solution, the first pins 20 are disposed on the side of the first base 11 facing away from the channel 12, the second pins 30 are disposed on the side of the second base 17 facing away from the channel 12, the included angle is disposed between the extension direction of each first pin 20 and the extension direction of the channel 12, and the included angle is disposed between the extension direction of each second pin 30 and the extension direction of the channel 12, so that the first pins 20 are located on the same side of the first base 11, the second pins 30 are located on the same side of the second base 17, and the first pins 20 and the second pins 30 are located on different sides of the lead frame 10. That is, pins with the same electrical property may be located on the same side of the lead frame 10, facilitating the subsequent testing of the LED device by technicians.

Further, the pins with the same electrical property are located on the same side of the lead frame 10 and the pins with different electrical properties are located on different sides of the lead frame 10, which is convenient for technicians to distinguish between positive and negative poles of an electrode, thereby facilitating the subsequent soldering and repairing of the LED device by technicians.

Further, the preceding arrangement reduces the area of a lateral electrode, reduces the amount of tin reaching the copper layer, the copper layer on the tin, and prevents the flux from intruding into the bracket at a high temperature.

Specifically, as shown in FIG. 2, in embodiment one of the present disclosure, a bottom surface of each first pin 20 is coplanar with a bottom surface of the first base 11, and a bottom surface of each second pin 30 is coplanar with a bottom surface of the second base 17. This arrangement better facilitates the mounting of the LED device.

Specifically, in embodiment one of the present disclosure, the first pins 20 and the second pins 30 are symmetrical about the channel, facilitating subsequent testing.

Specifically, in embodiment one of the present disclosure, the first lead portion includes two first pins 20 which are symmetrical, and the second lead portion includes two second pins 30 which are symmetrical. Compared with a single middle electrode (a traditional electrode), this arrangement reduces the offset during soldering.

As shown in FIGS. 2 and 5, in embodiment one of the present disclosure, an included angle A is disposed between the extension direction of the first pin 20 and the extension direction of the channel 12, where the included angle A satisfies that A=90°±10°. Alternatively or additionally, an included angle B is disposed between the extension direction of the second pin 30 and the extension direction of the channel 12, where the included angle B satisfies that B=90°±10°.

With the preceding arrangement, the first pin 20 may extend in a direction away from the channel 12, and the second pin 30 may extend in a direction away from the channel 12. Moreover, the first pins 20 may extend in the same direction, and the second pins 30 may also extend in the same direction. This arrangement facilitates the subsequent testing of the LED device by technicians.

As shown in FIGS. 3 and 5, in embodiment one of the present disclosure, the lead frame 10 further includes a plurality of indentations 14. The indentations 14 are spaced apart on a surface of at least one of the first base 11 or the second base 17 facing the chip 1.

In the preceding technical solution, the indentations 14 are disposed on the surface of at least one of the first base 11 or the second base 17 so that part of the molded structure 40 can be filled in the indentations 14, thereby increasing the connection area between the lead frame 10 and the molded structure 40 and thus increasing the air tightness between the lead frame 10 and the molded structure 40. Further, this arrangement effectively increases the binding force between the lead frame 10 and the molded structure 40.

Specifically, in embodiment one of the present disclosure, the indentations 14 are disposed on the side of at least one of the first base 11 or the second base 11 facing the chip 1.

Specifically, in embodiment one of the present disclosure, the indentations 14 are spaced apart on the surface of at least one of the first base 11 or the second base 17 in the first direction. Of course, in an alternative embodiment not shown in the drawings, the indentations 14 may also be spaced apart on the surface of at least one of the first base 11 or the second base 17 in the second direction.

Specifically, as shown in FIG. 3, in embodiment one of the present disclosure, the molded structure includes the chip placement body 61 and the reflective structure disposed around the periphery of the chip placement body 61. The chip placement body 61 defines the avoidance groove 62. The indentations 14 are disposed at a junction of the reflective structure and the lead frame 10, preferably in a central region between the avoidance groove 62 and an edge of the lead frame 10.

Preferably, in embodiment one of the present disclosure, each indentation 14 is a recess, which is easy to process. Of course, in an alternative embodiment not shown in the drawings, the indentation 14 may also be a raised strip. However, the processing of the raised strip is difficult.

As shown in FIGS. 3 and 5, in embodiment one of the present disclosure, the indentations 14 extend in the second direction. In the first direction perpendicular to the extension direction of the channel 12, the indentations 14 are located on the end of the first base 11 or the second base 17 farther from the channel 12.

In the preceding technical solution, the connection area between the molded structure 40 and the end of the first base 11 or the second base 17 farther from the channel 12 is relatively large. Accordingly, the indentations 14 are disposed on the end of the first base 11 or the second base 17 farther from the channel 12 so that the binding force between the lead frame 10 and the molded structure 40 is greatly increased, the deformation capability of the lead frame 10 at high temperature is reduced, and thus the reliability of the lead frame 10 is improved.

As shown in FIGS. 1, 2, and 5, in embodiment one of the present disclosure, the lead frame 10 includes two first pins 20 spaced apart in the extension direction of the channel 12.

In the preceding technical solution, the arrangement of two first pins 20 reduces the possibility of the flux intruding from a pin into a functional region of the LED device, thereby avoiding damage to the LED device and thus improving the reliability of the LED device.

Of course, in an alternative embodiment not shown in the drawings, the number of first pins 20 may be, for example, three or four.

As shown in FIGS. 1, 2, and 5, in embodiment one of the present disclosure, the lead frame 10 includes two second pins 30 spaced apart in the extension direction of the channel 12.

Of course, in an alternative embodiment not shown in the drawings, the number of second pins 30 may be, for example, three or four.

As shown in FIG. 2, in embodiment one of the present disclosure, the molded structure 40 includes second arc-shaped structures 42 connected to the first pins 20 of the lead frame 10. At least one side of each first pin 20 is provided with a second arc-shaped structure 42. The molded structure 40 includes third arc-shaped structures 43 connected to the second pins 30 of the lead frame 10. At least one side of each second pin 30 is provided with a third arc-shaped structure 43.

The preceding arrangement reduces the concentrated stress at the connection between the first pins 20 and the molded structure 40 and the concentrated stress at the connection between the second pins 30 and the molded structure 40, thereby improving the connection stability between the first pins 20 and the molded structure 40 and the connection stability between the second pins 30 and the molded structure 40. Further, the preceding arrangement facilitates the demolding of the molded structure 40.

Preferably, as shown in FIG. 2, in embodiment one of the present disclosure, two opposite sides of each first pin 20 are each provided with a second arc-shaped structure 42.

Of course, in an alternative embodiment not shown in the drawings, one side of each first pin 20 may be provided with a second arc-shaped structure 42.

Preferably, as shown in FIG. 2, in embodiment one of the present disclosure, two opposite sides of each second pin 30 are each provided with a third arc-shaped structure 43.

Of course, in an alternative embodiment not shown in the drawings, one side of each second pin 30 may be provided with a third arc-shaped structure 43.

### Embodiment Two

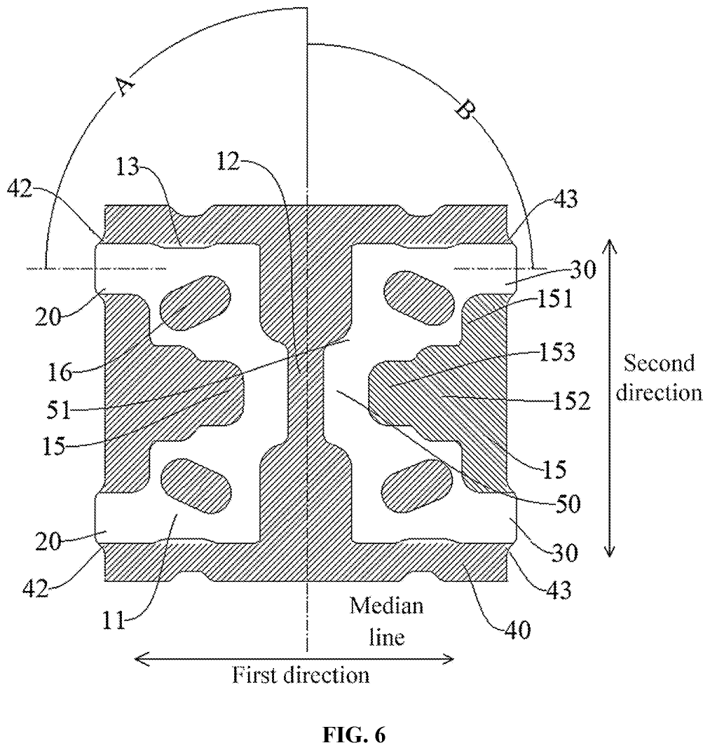

As shown in FIG. 6, the difference between embodiment two of the present disclosure and embodiment one of the present disclosure lies in that, in embodiment two, an included angle is disposed between the length direction of the elongated hole and the extension direction of the channel 12, and the distance between the lower end of the elongated hole and the median line of the channel 12 is greater than the distance between the upper end of the elongated hole and the median line of the channel 12. This arrangement also increases the connection area between the lead frame 10 and the molded structure 40, thereby increasing the binding force between the lead frame 10 and the molded structure 40.

Other structures of the bracket in embodiment two of the present disclosure are the same as those in embodiment one, which is not repeated here.

### Embodiment Three

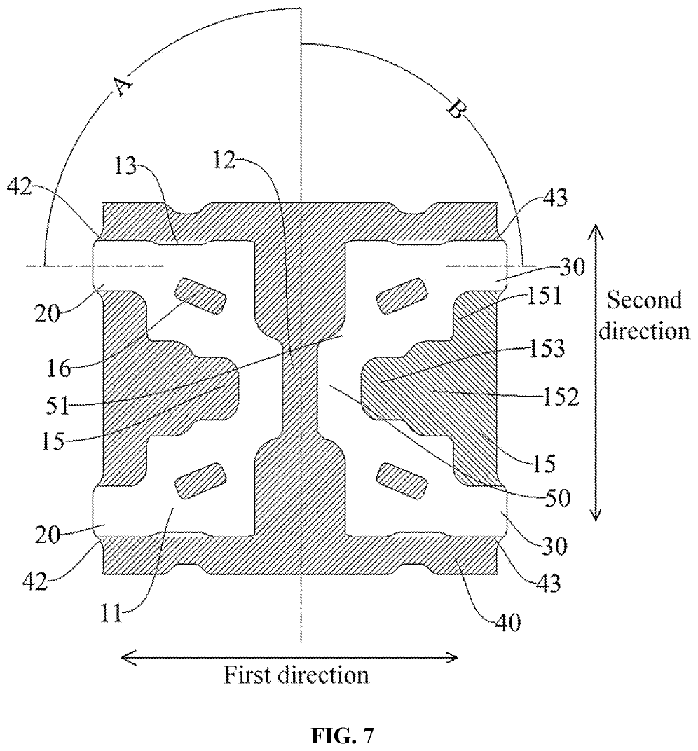

As shown in FIG. 7, the difference between embodiment three of the present disclosure and embodiment one of the present disclosure lies in that the through hole 16 is a square through hole with rounded corners in embodiment three. This arrangement also increases the connection area between the lead frame 10 and the molded structure 40, thereby increasing the binding force between the lead frame 10 and the molded structure 40.

Other structures of the bracket in embodiment three of the present disclosure are the same as those in embodiment one, which is not repeated here.

### Embodiment Four

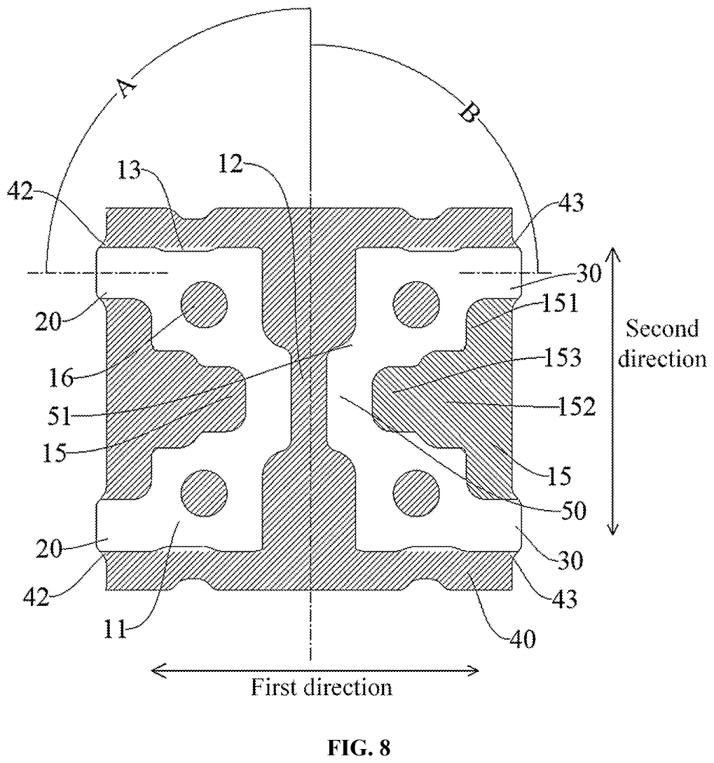

As shown in FIG. 8, the difference between embodiment four of the present disclosure and embodiment one of the present disclosure lies in that the through hole 16 is a circular through hole in embodiment four. Compared with the elongated hole, the circular through hole is more simple in structure and easy to process.

Other structures of the bracket in embodiment four of the present disclosure are the same as those in embodiment one, which is not repeated here.

### Embodiment Five

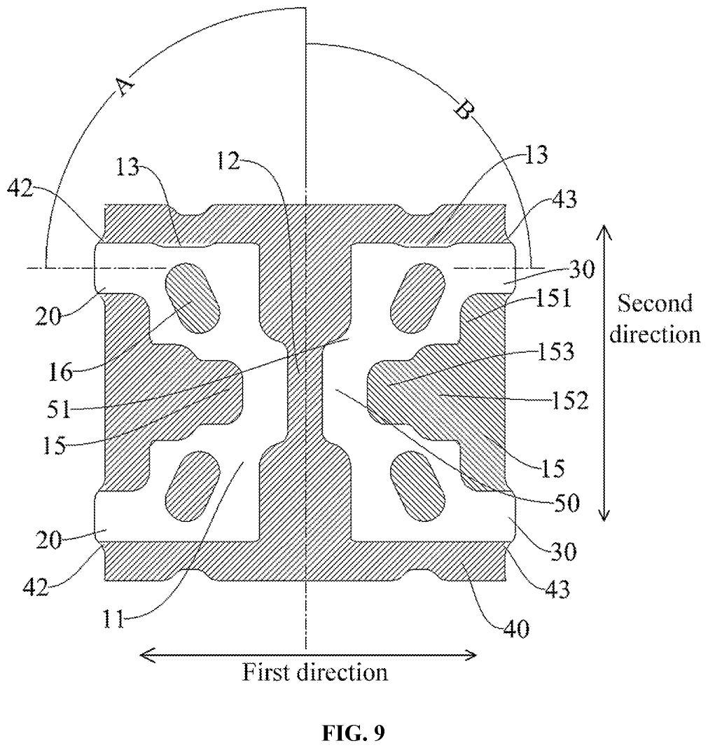

As shown in FIG. 9, the difference between embodiment five of the present disclosure and embodiment one of the present disclosure lies in that in embodiment five, only one side of the first base 11 and one side of the second base 17 are each provided with a first recessed groove 13 in the extension direction of the channel 12 (that is, the second direction), while no first recessed groove 13 is disposed on the other side of the first base 11 or the other side of the second base 17. This arrangement also effectively improves the air tightness between the lead frame 10 and a to-be-connected member. Further, this arrangement also increases the binding force between the lead frame 10 and the to-be-connected member.

Other structures of the bracket in embodiment five of the present disclosure are the same as those in embodiment one, which is not repeated here.

### Embodiment Six

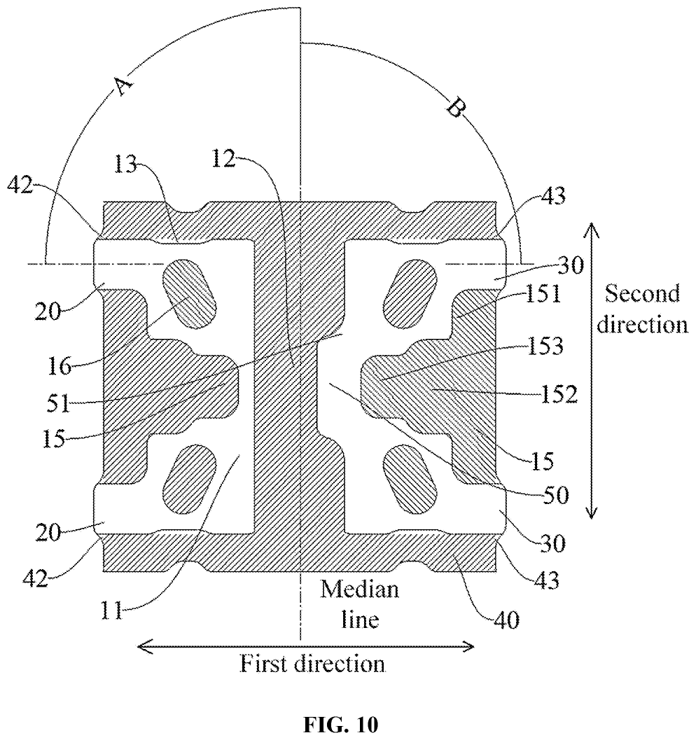

As shown in FIG. 10, the difference between embodiment six of the present disclosure and embodiment one of the present disclosure lies in that in embodiment six, one side of the first base 11 or the second base 17 facing the channel 12 is provided with a blocking structure 50. With this arrangement, the width of each of two ends of the channel 12 is greater than the width of the middle part of the channel 12 so as to form the “wide-narrow-wide” pattern, providing an enough soldering area for the soldering between the lead frame 10 and the chip 1, reducing the possibility of the flux intruding into the chip placement region, thereby avoiding the problem of reduced air tightness due to the thermal deformation of the lead frame 10 during soldering, and thus improving the reliability of the LED device.

Other structures of the bracket in embodiment six of the present disclosure are the same as those in embodiment one, which is not repeated here.

### Embodiment Seven

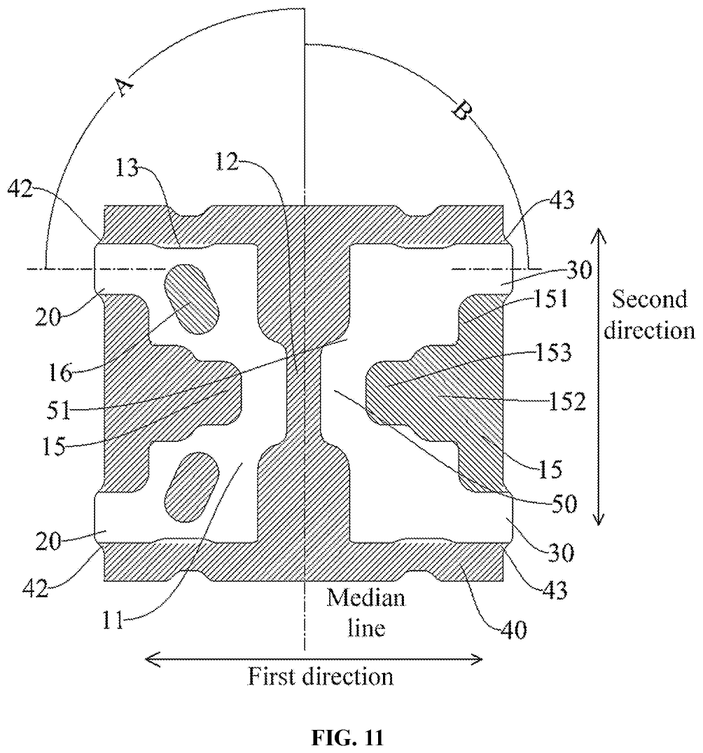

As shown in FIG. 11, the difference between embodiment seven of the present disclosure and embodiment one of the present disclosure lies in that the through hole 16 is disposed on the first base 11 or the second base 17 in embodiment seven. This arrangement enables the inner wall of the through hole 16 to be combined with the molded structure 40, thereby increasing the connection area between the lead frame 10 and the molded structure 40 and thus increasing the binding force between the lead frame 10 and the molded structure 40.

Other structures of the bracket in embodiment seven of the present disclosure are the same as those in embodiment one, which is not repeated here.

### Embodiment Eight

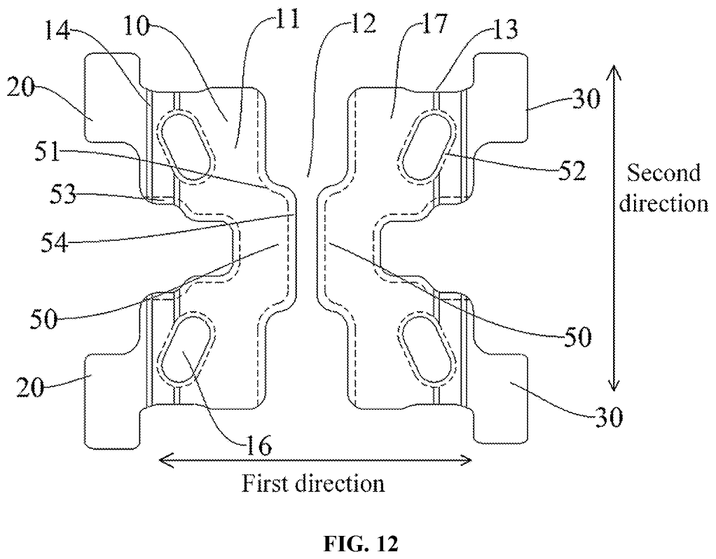

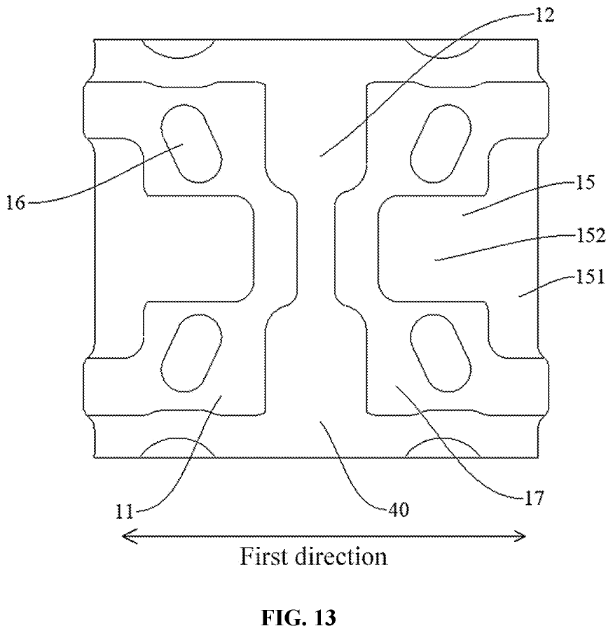

As shown in FIG. 12, the difference between embodiment eight of the present disclosure and embodiment one of the present disclosure lies in that in embodiment eight, the extension direction of each first pin 20 is parallel to the extension direction of the channel 12, and the extension direction of each second pin 30 is parallel to the extension direction of the channel 12. With the preceding arrangement, the structure is simple and easy to process.

Other structures of the bracket in embodiment eight of the present disclosure are the same as those in embodiment one, which is not repeated here.

### Embodiment Nine

As shown in FIG. 12, the difference between embodiment nine of the present disclosure and embodiment one of the present disclosure lies in that in embodiment nine, the second recessed groove 15 includes only a first groove segment 151 and a second groove segment 152 communicating with each other, and in the first direction toward the channel 12, the widths of the two groove segments decrease successively.

The preceding arrangement improves the plastic fluidity of the molded structure 40 during injection molding so that the inside of the injection molding of the bracket is fuller, reducing the possibility of generating a bubble.

Other structures of the bracket in embodiment nine of the present disclosure are the same as those in embodiment one, which is not repeated here.

### Embodiment Ten

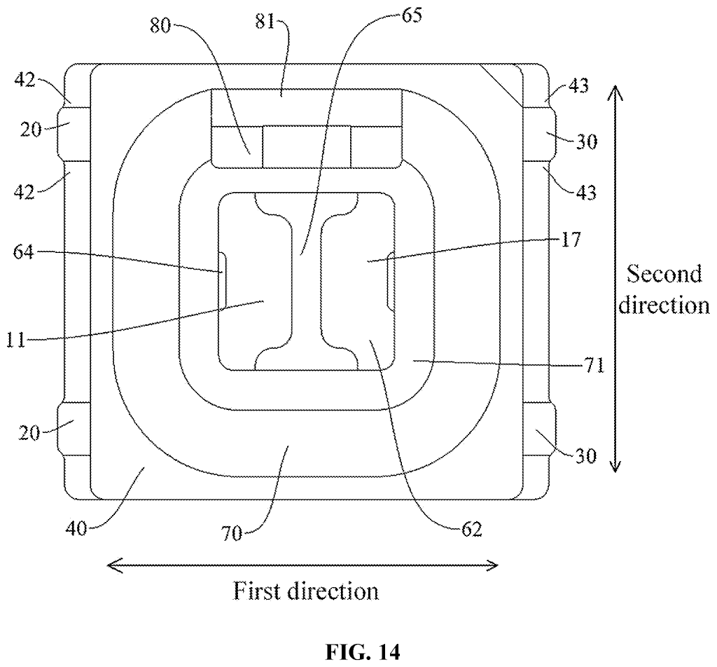

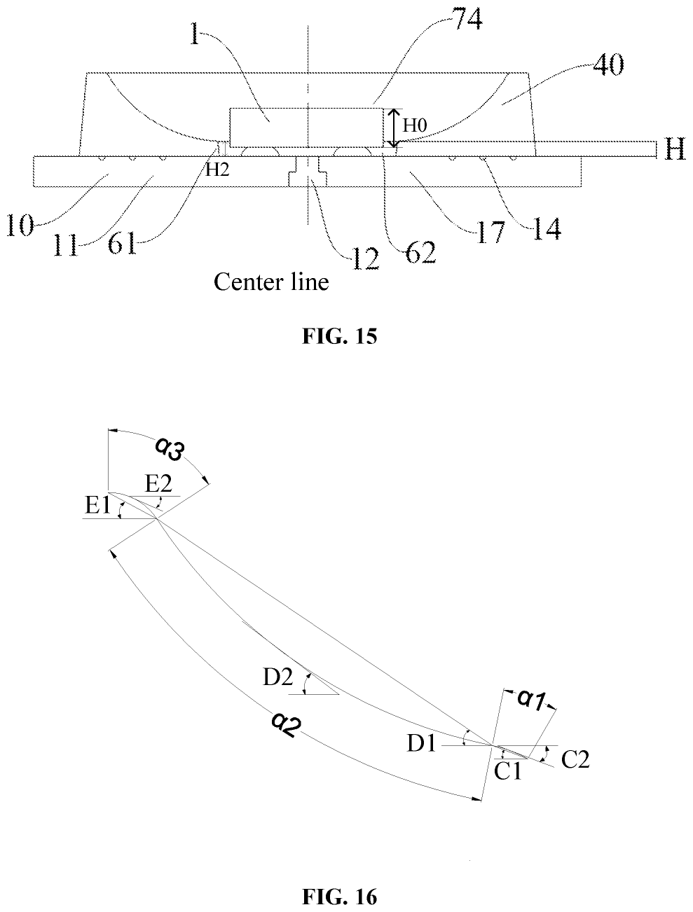

As shown in FIGS. 14 and 15, the difference between embodiment ten of the present disclosure and embodiment one of the present disclosure lies in that in embodiment ten, the chip placement body 61 is not a step structure used for mounting the chip 1, the chip 1 is mounted in the avoidance groove 62, and the projections of the reflective structure and the chip placement body 61 on the first plane partially cover the first protrusion 64, so that part of the first protrusion 64 is exposed from the avoidance groove 62.

The preceding structure is simple, which is convenient for processing and reduces processing costs.

Preferably, in embodiment ten of the present disclosure, the value of the length of the avoidance groove 62 is less than 1.2 times the value of the length of the chip 1 and is greater than the value of the length of the chip 1. This arrangement enables a certain distance between an inner wall surface of the avoidance groove 62 and the chip 1, thereby preventing a sidewall of the avoidance groove 62 from affecting the lateral light emission of the chip 1, enabling the light emitted from the chip 1 to be reflected through the sidewall of the avoidance groove 62, and thus improving the effect of light emission.

As shown in FIGS. 14 and 15, in embodiment ten of the present disclosure, the depth of the avoidance groove 62 is H2. The height of the chip 1 is H0h. The depth H satisfies that 0.15 H0≤H2≤0.5 H0. This arrangement enables most of the chip 1 to protrude from the avoidance groove 62, thereby preventing the lateral light emission of the chip 1 from being affected by an excessively great depth of the avoidance groove 62. Accordingly, most of the light emitted from the chip 1 is reflected through the reflective surface, thus improving the effect of light emission.

Specifically, in embodiment ten of the present disclosure, an exposed length of the first protrusion 64 in the second direction is 0.2 times to 0.6 times the length of the avoidance groove 62, and an exposed length of the first protrusion 64 in the first direction is 0.3 times to 0.5 times the width of the middle part of the blocking member 65.

Preferably, in embodiment ten of the present disclosure, the exposed length of the first protrusion 64 in the second direction is 0.36 mm, and the exposed length of the first protrusion 64 in the first direction is 0.04 mm.

Other structures of the bracket in embodiment ten of the present disclosure are the same as those in embodiment one, which is not repeated here.

It can be seen from the preceding description that the preceding embodiments of the present disclosure implement the following technical effects: the reflective structure extends in the circumferential direction and is connected to the chip placement body in the entire circumferential direction so that the reflective structure has a relatively large reflective surface. That is, all the space of the molded structure except for the chip placement body is formed with the reflective structure. In this case, the reflective surface with a large area can reflect the light emitted from the chip located on the chip placement body, thereby effectively improving the light emission rate.

The scope of the present disclosure is not limited to the preceding embodiments. It is to be understood by those skilled in the art that various modifications, combinations, subcombinations, and substitutions may be made according to design requirements and other factors. Any modifications, equivalent substitutions, improvements, and the like made within the spirit and principle of the present disclosure fall within the scope of the present disclosure.

What is claimed is:

1. An LED device, wherein the LED device comprises a bracket and a chip, the bracket comprises a lead frame and a molded structure connected to the lead frame, and the molded structure comprises:
a chip placement body defining an avoidance groove; and
a reflective structure, wherein the reflective structure is a cylindrical structure with an inner through hole; the inner through hole communicates with the avoidance groove; the cylindrical structure is disposed around a periphery of the chip placement body; a first end of the cylindrical structure is formed with an opening communicating with the inner through hole; a second end of the cylindrical structure is connected to the chip placement body in an entire circumferential direction; a circumferential sidewall of the inner through hole forms a reflective surface used for reflecting light; and from the second end of the cylindrical structure to the first end of the cylindrical structure, the reflective surface comprises a plurality of arc-shaped surfaces that are successively connected.

2. The LED device according to claim 1, wherein the plurality of arc-shaped surfaces comprise a first arc-shaped surface and a second arc-shaped surface that are connected to each other, the first arc-shaped surface and the second arc-shaped surface are each inclined relative to a horizontal plane, and the first arc-shaped surface and the second arc-shaped surface are each inclined in a direction gradually away from a center line of the cylindrical structure.

3. The LED device according to claim 2, wherein a first included angle C1 is disposed between the first arc-shaped surface and the horizontal plane, and the first included angle C1 satisfies that 25°≤C1≤50°; and/or a second included angle D1 is disposed between the second arc-shaped surface and the horizontal plane, and the second included angle D1 satisfies that 30°≤D1≤45°.

4. The LED device according to claim 2, wherein the first arc-shaped surface protrudes toward a side where the center line is located, the first arc-shaped surface has a first radian α1, and 10°≤α1≤30°; and/or the second arc-shaped surface protrudes in the direction away from the center line, the second arc-shaped surface has a second radian α2, and 40°≤α2≤80°.

5. The LED device according to claim 2, wherein a first included angle C2 is disposed between the first arc-shaped surface and the horizontal plane, the first included angle C2 increases first and then decreases in the direction away from the center line; a second included angle D2 is disposed between the second arc-shaped surface and the horizontal plane, and the second included angle D2 increases gradually in the direction away from the center line.

6. The LED device according to claim 2, wherein the plurality of arc-shaped surfaces further comprise a third arc-shaped surface connected to the second arc-shaped surface, and the third arc-shaped surface is inclined relative to the horizontal plane and in the direction gradually away from the center line of the cylindrical structure.

7. The LED device according to claim 6, wherein a third included angle E1 is disposed between the third arc-shaped surface and the horizontal plane, and the third included angle E1 satisfies that 30°≤E1≤40°; and/or the third arc-shaped surface protrudes toward a side where the center line is located, the third arc-shaped surface has a third radian α3, and 40°≤α3≤80°.

8. The LED device according to claim 6, wherein a first included angle C2 is disposed between the first arc-shaped surface and the horizontal plane, a second included angle D2 is disposed between the second arc-shaped surface and the horizontal plane, a third included angle E2 is disposed between the third arc-shaped surface and the horizontal plane, the first included angle C2 increases first and then decreases in the direction away from the center line, the second included angle D2 increases gradually in the direction away from the center line, and the third included angle E2 decreases gradually in the direction away from the center line.

9. The LED device according to claim 1, wherein the chip placement body is a step structure used for mounting the chip.

10. The LED device according to claim 9, wherein 0.7 W0≤W1≤0.9 W0, wherein W0 represents a width of the chip, and W1 represents a width of the avoidance groove; or 0.15 H0≤H1≤0.35 H0, wherein H0 represents a height of the chip, and H1 represents a height of the step structure; or 0.03 mm≤H1≤0.08 mm, wherein H1 represents a height of the step structure.

11. The LED device according to claim 1, wherein the molded structure further comprises a blocking member extending in a second direction and connected to the chip placement body, the blocking member is located on a side of the avoidance groove facing away from the inner through hole, and a width of an end of the blocking member closer to the inner through hole is less than a width of an end of the blocking member farther from the inner through hole.

12. The LED device according to claim 1, wherein the lead frame comprises:
a first lead portion comprising a first base;
a second lead portion comprising a second base spaced apart from the first base, wherein a space between the first base and the second base forms a channel, the first lead portion and the second lead portion are insulated from each other, and part of the molded structure is filled in the channel; and
a blocking structure, wherein a side of at least one of the first base or the second base facing the channel is provided with the blocking structure; in an extension direction of the channel, the blocking structure is located between two opposite ends of the at least one of the first base or the second base and protrudes from the least one of the first base 11 or the second base 17; part of the molded structure is located on a side of the lead frame; and the blocking structure is exposed from the avoidance groove.

13. The LED device according to claim 12, wherein the lead frame further comprises a second recessed groove, the second recessed groove is disposed on a side of at least one of the first base or the second base facing away from the channel, the molded structure further comprises a first protrusion connected to the reflective structure, and the second recessed groove matches the first protrusion in shape and size.

14. The LED device according to claim 13, wherein a projection of the reflective structure on a first plane and a projection of the chip placement body on the first plane completely cover the first protrusion to prevent the first protrusion from being exposed from the avoidance groove, or a projection of the reflective structure on a first plane and a projection of the chip placement body on the first plane partially cover the first protrusion to enable part of the first protrusion to be exposed from the avoidance groove.

15. The LED device according to claim 12, wherein a through hole is disposed on at least one of the first base or the second base, a second protrusion is disposed on a side of the molded structure, and the second protrusion matches the through hole in shape and size.

16. The LED device according to claim 1, further comprising at least one accommodation groove disposed on an inner wall surface of the cylindrical structure, wherein the at least one accommodation groove is used for accommodating a Zener diode, and each of the at least one accommodation groove communicates with the inner through hole and is spaced apart from the avoidance groove.

17. The LED device according to claim 16, wherein an inclined surface is disposed on a sidewall of each of the at least one accommodation groove facing away from the chip placement body; and from the second end of the cylindrical structure to the first end of the cylindrical structure, the inclined surface extends gradually away from a center line of the inner through hole.

18. The LED device according to claim 17, wherein the inclined surface extends from the sidewall of the at least one accommodation groove to the first end of the cylindrical structure.

19. The LED device according to claim 1, wherein the molded structure further comprises a reflective member covering the at least one accommodation groove and used for reflecting light.

20. The LED device according to claim 1, wherein the molded structure comprises a plurality of accommodation grooves spaced apart in a circumferential direction of the avoidance groove.
